(19) United States
(12) Patent Application Publication
(10) Pub. No.: US 2018/0003739 A1
(43) Pub. Date: Jan. 4, 2018

(54) PLUG-THROUGH POWER METER WITH PLANAR PROFILE

(71) Applicant: THE REGENTS OF THE UNIVERSITY OF MICHIGAN, Ann Arbor, MI (US)

(72) Inventors: Samuel DEBRUIN, Ann Arbor, MI (US); Branden GHENA, Ann Arbor, MI (US); Prabal DUTTA, Ann Arbor, MI (US)

(21) Appl. No.: 15/638,941

(22) Filed: Jun. 30, 2017

Related U.S. Application Data
(60) Provisional application No. 62/356,940, filed on Jun. 30, 2016.

(51) Int. Cl. G01R 11/02; H01R 24/78; G01R 11/04; H01R 103/00

(52) U.S. Cl. CPC G01R 11/02; H01R 24/78; G01R 11/04; H01R 2103/00

(57) ABSTRACT

An improved energy meter is presented that achieves a vastly smaller form factor than prior systems. The energy meter occupies an unobtrusive and essentially two-dimensional volume, 1″×1″× 1/16″, and meters loads plugged through it and into an outlet. Despite its small size, the energy meter is a wireless true power meter, capable of metering real, reactive, and apparent power at kHz frequencies, aggregating these measurements into cumulative energy, and transmitting these data several times per second using a Bluetooth Low Energy (BLE) radio to a nearby smart phone or gateway. At a cost of $11 in modest quantities of 1,000 units, the energy meter is the smallest and lowest cost AC plug-load meter with 1.13% accuracy over a 2-1200 W range for unity power factor loads, and slightly worse for non-linear and reactive loads. This small form factor, coupled with easy access to and transport of the meter data, enables new applications.

### CROSS-REFERENCE TO RELATED APPLICATIONS

This application claims the benefit of U.S. Provisional Application No. 62/356,940, filed on Jun. 30, 2016. The entire disclosure of the above application is incorporated herein by reference.

### GOVERNMENT CLAUSE

This invention was made with government support under Grant Nos. CNS1350967; CPS1505684 and DGE1256260 awarded by the National Science Foundation. The Government has certain rights in this invention.

### FIELD

The present disclosure relates to a plug-through power meter with planar profile.

### BACKGROUND

Residential and commercial buildings in the United States used 2,760 TWh of electrical energy in 2014. The majority of that usage comes from clearly obvious loads including HVAC, lighting, and appliances, however, approximately a 20% (and growing) share of electricity usage is due to “plug-loads,” often called miscellaneous electrical loads (MELS) in industry terms. These diverse loads, from television and computers to vending machines and box fans, represent the long-tail of electricity use. Understanding the characteristics of these loads requires insight into each device's individual consumption but the methods today are limited. As a result, ratepayers, regulators, and researchers lack the tools to unobtrusively monitor plug-load energy use with high fidelity and low cost.

To help address this problem, this disclosure presents an improved power/energy meter that achieves a vastly smaller form factor than prior systems (referred to herein as PowerBlade meter).

This section provides background information related to the present disclosure which is not necessarily prior art

### SUMMARY

This section provides a general summary of the disclosure, and is not a comprehensive disclosure of its full scope or all of its features.

An energy meter is presented for use with a device having a power cord. The energy meter is constructed on a circuit board having a set of holes configured for prongs of an electric plug to pass therethrough. A current sense circuit, a voltage sense circuit and a controller are mounted onto the circuit board. The current sense circuit includes an inductor that is disposed proximate to a given hole in the set of holes and configured to measure magnetic field generated by current flowing through a prong passing through the given hole. The voltage sense circuit is configured to measure voltage between two specific prongs passing through the set of holes, where the voltage sense circuit includes input terminals that physically contacts the two specific prongs and electrically couples the two specific prongs to the voltage sense circuit. The controller computes electrical power of load supplied by the electric plug from the measured magnetic field and the measured voltage.

In one aspect, the inductor in the current sense circuit is orientated such that windings of the inductor wind around an axis that is parallel to a plane defined by the circuit board. The inductor of the current sense circuit may be further defined as a wirewound inductor.

In another aspect, at least one of the input terminals for the voltage sense circuit is a conductive member integrated into and coplanar with the circuit board, where the conductive member protrudes inwardly from a side wall defining the hole through which the specified prong passes through.

The energy meter may further include a power supply circuit configured to receive AC voltage from the prongs of the electrical plug and operates to rectify and down convert the AC voltage to a lower DC voltage. In one embodiment, the power supply circuit is further defined as a Zener regulated power supply with a passive input impedance element and a half-wave rectifier.

The energy meter may also include a wireless interface mounted to the circuit board and interfaced with the microcontroller to report the computed electrical power.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a perspective view of an energy meter with the plug of a power cord passing therethrough;

FIGS. 1B and 1C are a front view and a profile view of the proposed energy meter, respectively;

FIG. 2 is a block diagram of the components comprising the proposed energy meter;

FIG. 3 is a schematic of an example embodiment of a voltage sense circuit;

FIG. 4 is a schematic for an example embodiment of a current sense circuit;

FIG. 5 is a schematic of an example embodiment of a power supply circuit;

FIG. 6 is a chart illustrating the tradeoffs for selecting a passive circuit element in the power supply circuit;

FIGS. 7A and 7B are diagrams showing the showing the magnetic fields around the prongs of an AC plug;

FIG. 8 is a graph depicting the maximum energy quanta in relation to the recharge rate for two different passive circuit element options;

FIGS. 9A and 9B are cross-sectional views of a circuit board having electrical contacts integrated therein;

FIG. 10 is a graph showing the uncalibrated RMS current for the proposed energy meter;

FIG. 11 is a graph showing the system current of the proposed energy meter during a startup phase;

FIG. 12 is a graph showing the metering accuracy of the proposed energy meter for a variable resistive load;

FIG. 13 is a graph illustrating the current waveforms for different loads as measured by the proposed energy meter;

FIG. 14 is a graph illustrating the metering accuracy for a television in use; and

FIGS. 15A and 15B are graphs showing the unique packets received and total packets received from a wireless transmitter integrated into the proposed energy meter.

Corresponding reference numerals indicate corresponding parts throughout the several views of the drawings.

### DETAILED DESCRIPTION

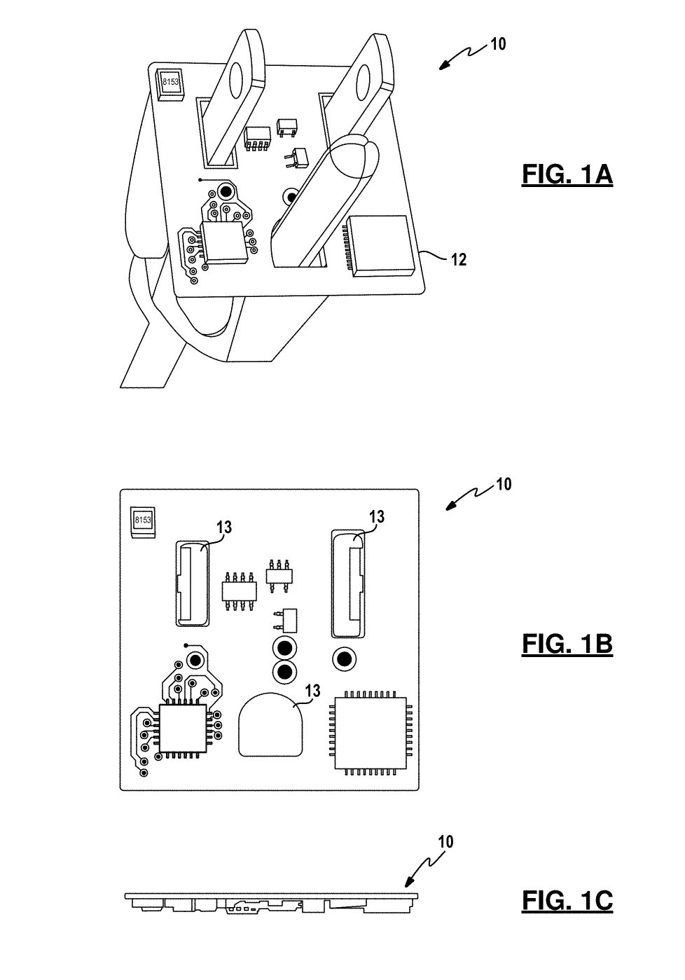

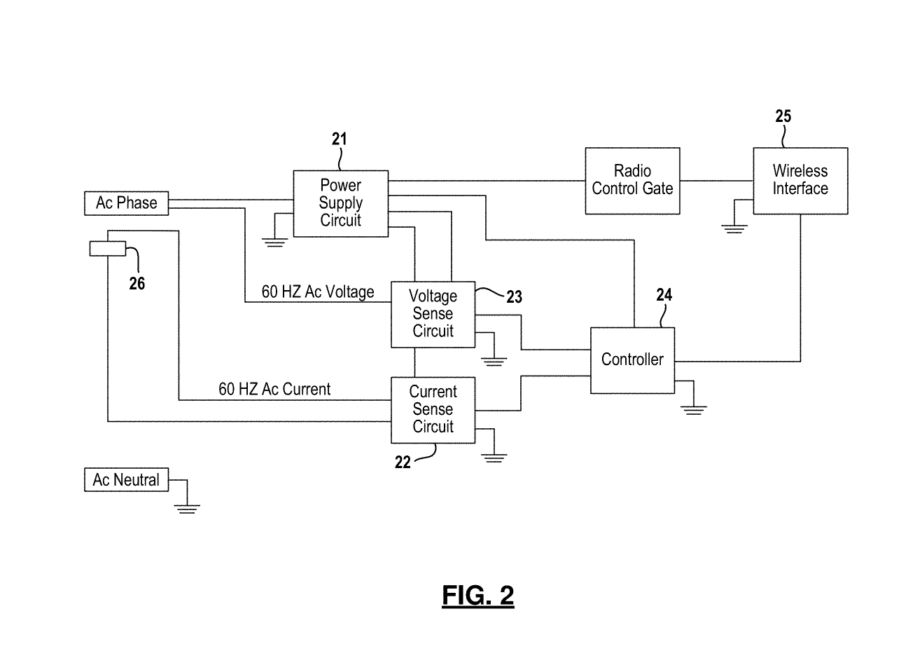

FIGS. 1A-1C illustrates an example embodiment of a proposed energy meter 10 with a much smaller form factor as compared to earlier systems. The energy meter 10 is constructed on a circuit board 12. In an example embodiment, the dimensions of the energy meter 10 are 1″×1″× 1/16″. The width and length of the circuit board 12 are preferably less than or equal to one inch by one inch to prevent overlap with other outlets, for example is accordance with NEMA standards; whereas, the thickness is preferably less than 3 mm. The circuit board 12 includes a set of cutouts (i.e., holes) 13 which are configured to receive the prongs of an electric plug as seen in FIG. 1A. It is readily understood that the cutouts may be configured and/or sized differently to accommodate other types of electric plugs.

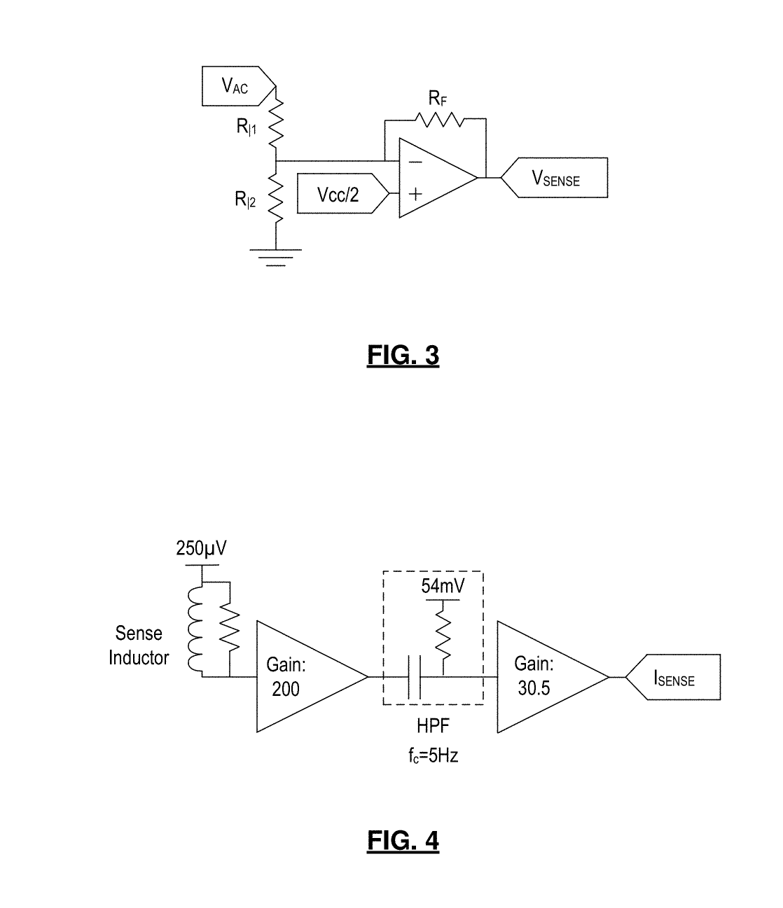

FIG. 2 depicts the primary components of the energy meter 10. The energy meter 10 includes a power supply 21, a current sense circuit 22, a voltage sense circuit 23, a controller 24 and a wireless interface 25. Each of these components are further described below. It is to be understood that only the most relevant components are discussed in relation to FIG. 2, but that other components may be needed to control and manage the overall operation of the system.

A power supply circuit 21 is mounted to the circuit board 12 and configured to supply electric power to the other components of the meter 12. For a power meter to operate from the AC mains, it must rectify and step down the AC voltage to provide itself with a lower DC voltage. Half- or full-wave rectifiers are typically used for this purpose, and they can occupy a small volume using a single or multiple low-profile diodes. Voltage step-down, in contrast, requires more volume and is not blindly amenable to scaling. Moreover, step-down techniques often do not scale as DC power is reduced, requiring a minimum volume regardless of the DC power supplied, while energy harvesters often require bulky current transformers that are fundamentally unsuited to a small form factor. In this disclosure, meter design eschews energy harvesters and transformers, due to scaling challenges, and instead embraces a Zener-regulated power supply as will be further described below. The key to making this design point viable is scaling the electronics power draw down to meet the limited supply. Other types of power supply circuit which meet these scaling challenges also fall within the scope of this disclosure.

The energy meter 10 must acquire time-synchronized voltage and current measurements and multiply them together to obtain power. The voltage channel can be obtained by intercepting the plug's prongs and using a voltage divider to obtain a scaled-down version of the voltage signal. Unfortunately, intercepting the power lines to obtain the voltage is not possible in a planar design. Other designs distribute the voltage and current measurements, and wirelessly recombine them, to obtain power, while others do not use the voltage channel signal at all. None of these approaches are ideal for a plug-through energy meter. Taking distributed measurements requires at least two different devices which increases cost and makes deployment cumbersome, while only using the current channel lead to errors for non-unity power factors.

In contrast, the voltage sense circuit 23 in the proposed energy meter 10 is configured to measure voltage between two of the prongs (i.e., AC phase prong and AC neutral prong) passing through the holes formed in the circuit board 12. An example voltage sense circuit 23 is shown in FIG. 3. The voltage sense circuit 23 measures line voltage V_{AC} directly through a voltage divider with a V_{CC}/2 offset to measure both positive and negative phases. In an example embodiment, R_{F}=4.99 k′Ω and R_{I 1}=R_{I 2}=953 k′Ω, so V_{SENSE} can be approximated as

$${V}_{SENSE} \approx \frac{{V}_{CC}}{2} - 5.24 \times {10}^{- 3} {V}_{A C} \qquad ( 1 )$$

Based on these configurations, the voltage signal has a peak to peak amplitude of 1.79 V where the AC is 120 V_{RMS} (United States) and 3.28 V where the AC is 220 V_{RMS} (much of Europe and China). While an exemplary embodiment of the voltage sense circuit 23 has been described above with specific components having specific values and arranged in a specific configuration, it will be appreciated that this circuit may be constructed with many different configurations, components, and/or values as necessary or desired for a particular application. The above configurations, components and values are presented only to describe one particular embodiment that has proven effective and should be viewed as illustrating, rather than limiting, the present invention.

In the example embodiment, the voltage sense circuit 23 includes two input terminals that physically contact the two specified prongs and electrically couples the specified prongs to the voltage sense circuit. More specifically, one input terminal for the voltage sense circuit 23 is a conductive member integrated into and coplanar with the circuit board 12, such that the conductive member protrudes inwardly from a side wall defining the hole through which the specified prong passes through as will be further described below. By integrating the contacts directly into the circuit board, the meter design makes contact with the prongs without the need for an AC receptacle.

Among power meters, the most common methods for measuring current employ a sense resistor placed in series with the electrical path, a Hall effect sensor placed co-planar to a current carrying conductor trace, and a current transformer (CT) that encircles the current carrying conductor. Unfortunately, none of these designs are suited to an essentially planar, plug-through form factor. Current sense resistors are inexpensive, accurate, and small, but they require the electrical path to be broken and an AC receptacle and prongs be used, making them unsuitable for this application. Hall effect sensors work by measuring the deflection of electrons in a conductor exposed to a magnetic field (like the one generated by a current). However, they require the magnetic field lines to be perpendicular to the plane of the sensing element which, in our case, is challenging since the magnetic field lines are co-planar with the circuit board; hence a Hall effect sensor would require a non-trivial third dimension.

In contrast with these methods of current sensing, the proposed energy meter uses an optimally-placed surface mount inductor to measure the variation in magnetic flux produced by a current carrying conductor, detectable as a voltage across the inductor's terminals. In an example embodiment, the current sense circuit 22 includes an inductor that is disposed proximate to a given cutout in the set of cutouts and is configured to measure magnetic field generated by current flowing through a prong passing through the given cutout. In particular, the inductor is a horizontally wirewound inductor mounted on the circuit board, such that the axis of the inductor windings is parallel to the plane of the circuit board. Used in this way, the inductor functions as a search coil (or inductive sensor) whose terminal voltage is proportional to the rate of change of the current over time. This approach requires signal integration to recover the original current signal. Using a small, surface mount inductor in this manner enables the energy meter 10 to maintain an essentially two-dimensional form factor-something that is difficult using conventional current sensing methods.

FIG. 4 illustrates an example embodiment for the current sensing circuit 22. The current sense circuit 22 measures the signal from the sense inductor in multiple stages. The inductor is referenced to 250 μV and amplified in two stages with a combined gain of about 6100×. Low frequency noise is removed with a high pass filter between the first and second stages, and this filter is referenced to 54 mV so the final signal is centered around V_{CC}/2.

$${V}_{SENSE} \approx \frac{{V}_{CC}}{2} + α \frac{dI}{dt} \qquad ( 2 )$$

Equation (2) describes the output of the current sense stage as a function of the derivative of the AC current, where a is a lumped parameter consisting of the characteristics of the coil, gain, signal distortions, and general uncertainty. After integration the current is represented by Equation (3), where β accounts for DC offsets in the system and integration offsets.

$$Current \approx \int ( \frac{{V}_{CC}}{2} + α \frac{dI}{dt} ) dt \approx α I + β \qquad ( 3 )$$

As indicated above, the current sense circuit 22 has been described above with specific components having specific values and arranged in a specific configuration, it will be appreciated that this circuit may be constructed with many different configurations, components, and/or values as necessary or desired for a particular application. The above configurations, components and values are presented only to describe one particular embodiment that has proven effective and should be viewed as illustrating, rather than limiting, the present invention.

Returning to FIG. 2, the controller 24 is electrically coupled to the current sense circuit 22 and the voltage sense circuit 23. The controller 24 calculates power from the measured current and the measured voltage. In an exemplary embodiment, the controller 24 is implemented as a microcontroller, for example the MSP430FR5738 microcontroller from Texas Instruments. It should be understood that the controller 24 can be implemented in hardware logic, software logic, or a combination of hardware and software logic. In this regard, controller 24 can be or can include any of a digital signal processor (DSP), microprocessor, microcontroller, or other programmable device which are programmed with software implementing the above described methods. It should be understood that alternatively the controller is or includes other logic devices, such as a Field Programmable Gate Array (FPGA), a complex programmable logic device (CPLD), or application specific integrated circuit (ASIC). When it is stated that controller 24 performs a function or is configured to perform a function, it should be understood that the controller 24 is configured to do so with appropriate logic (such as in software, logic devices, or a combination thereof).

To be useful, the power meter 10 must communicate its data to the outside world. Thus, a wireless interface 25 is mounted to the circuit board and interfaced with the controller to report the computed power as well as other data. In one embodiment, the wireless interface 25 is defined as a wireless transmitter or a wireless transceiver. The wireless interface preferably employs Bluetooth Low Energy technology although other type of communication protocols may be employed as well. Bluetooth Low Energy technology directly leverage the rich interface available on nearby smartphones and will support IP connectivity and end-to-end networking.

Each of the five function performed by the power meter 10 are further examined within the small design space as well as the tradeoffs for achieving this design.

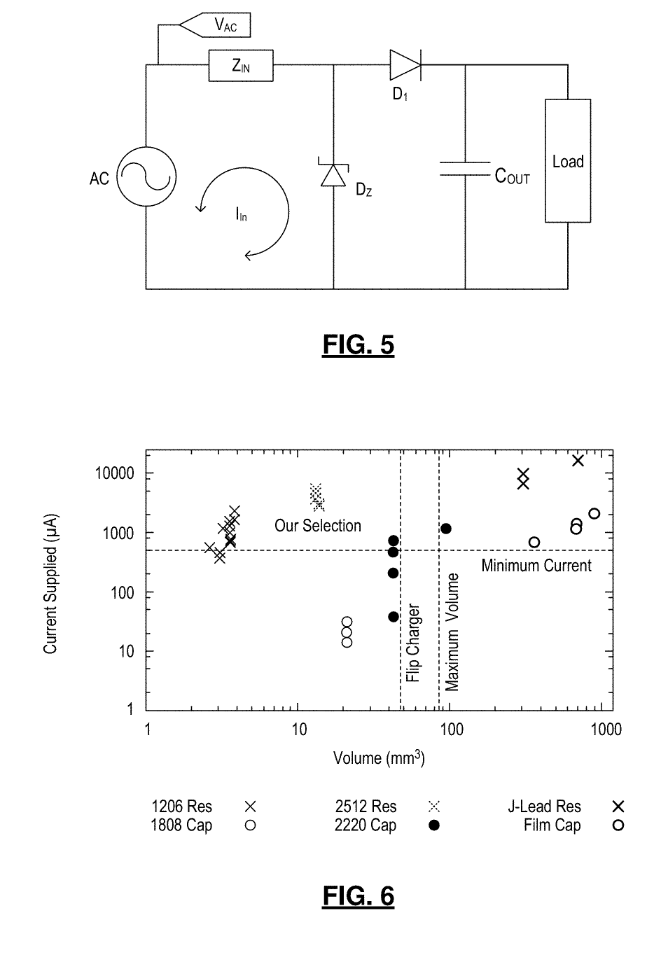

The power meter 10 is optimized for size by using a power supply design that does not require an IC. FIG. 5 depicts one example power supply circuit 30 for the power meter 10. The power supply circuit is a Zener regulated power supply with a passive input impedance element, Z_{IN}, and a half-wave rectifier. The passive input impedance element is in series between the positive terminal of the AC source and the rectifying diode D₁. This circuit offers a low component count, and only the passive input impedance, Z_{IN}, must be rated for AC voltage. The choice of Z_{IN} affect's the final systems available power, overall volume, and idle power draw. In this disclosure, components rated for the application are examined: leads separated by at least the AC mains spark gap of 1.25 mm (package 1206 and larger). Resistors are further rated for the idle power dissipated (V²_{AC}/R), and capacitors must be class X (AC rated “across the line”) or above.

Note that this power supply circuit 30 is not isolated. Its ground is tied directly to the neutral line, which could be a possible safety issue when interacting with the circuit. Since the system is wireless, and is intended to be entirely packaged, this does not present a risk for the end user. More discussion on packaging is provided below. One aspect of safety that does pertain here, however, is component count. In order to limit inrush current, if Z_{IN} is a capacitor, it must be in series with a resistor. Further, when the system is de-powered the capacitor maintains its voltage. In order to prevent shock, an additional high-value bleed resistor must be placed in parallel with the capacitor. If Z_{IN} is a resistor, neither extra component is required. Although this is not explicitly included in the volume discussion below, it must be considered when selecting the final design.

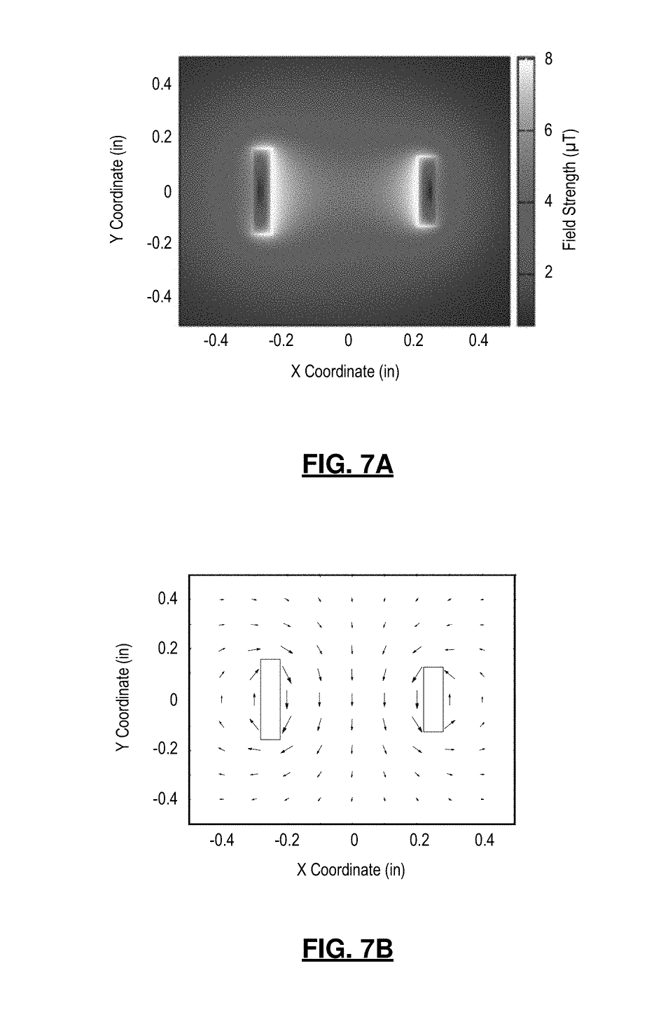

FIG. 6 shows the design space for Z_{IN} based on component volume and supplied current. A third parameter, not pictured, is idle power: the resistors add an idle power even when the load is not applied. This idle power scales directly with current supplied. Capacitors, however, do not affect idle power. The current draw follows Ohm's law (I_{MAX}≈V_{AC}/Z_{IN}). Volume is calculated using components from DigiKey's electronic component database, and for resistors the smallest available component with the required power rating is shown.

This figure illustrates the fundamental tradeoffs for this simple supply: the volume occupied by the supply scales directly with the provided current. In other words, current is not free even though the system is attached to AC. Whether for resistors or capacitors, accommodating more current means moving to a larger package. Even within a given package, small variations are introduced, while small variations in value result in quantum jumps in volume.

FIG. 6 can be used to determine an approximate power point for the system. This can be used to select the remainder of the components, which in turn will yield a more precise minimum required current. The maximum volume and minimum current shown on the figure are for the final system design. The range of acceptable volumes is determined experimentally on several NEMA outlets, with an additional dashed line representing an approximation of the Flip It USB charger's volume which also utilizes a very similar form factor and usage model.

The upper left quadrant of FIG. 6 is the viable design space for the proposed energy meter 10. In the example embodiment, the pareto-optimal point for current is a 10 k′Ω 2512 resistor that can supply 5.5 mA and requires 13.1 mm³. The pareto-optimal point for volume is a 47 k′Ω 1206 resistor that can supply 1.1 mA and requires 3.2 mm³. These would add and idle power of 1.4 W and 300 mW, respectively. The pareto-optimal point for idle power is a 33 nF 2220 ceramic capacitor that can supply 684 μA and requires 42.8 mm³, but adds no idle power. Based on this evaluation, different selections are available for the passive input impedance element Z_{IN}. In one embodiment, the passive input impedance element is a ceramic capacitor with an X2 rating. In another embodiment, the passive input impedance element is a 1210 resistor selected away from the frontier to provide ample tolerance in power dissipation. The selected resistor is just over the minimum current threshold to minimize idle power draw. It is readily understood from this evaluation that other types of capacitors and/or resistors may fall within the current and volume constraints of the energy meter design.

Many existing current sensing techniques, like shunt resistor, are planar, but rely on interrupting an AC conductor, which the proposed energy meter cannot do. Instead, the proposed energy meter 10 senses current non-intrusively by detecting the magnetic field surrounding an alternating current. As current passes through the AC prongs inserted through circuit board, the charge moving through each prong generates a magnetic field. Those fields add constructively between the prongs and destructively outside the prongs. FIGS. 7A and 7B, generated by applying the Biot-Savart law, shows the relative strength and orientation of this magnetic field in the plane of circuit board surrounding the prongs.

Two aspects of these figures guide the optimal placement of a sensor to measure this field. First, the magnitude of the field is on the order of 10-100 nT, which establishes bounds on the required transducer sensitivity. Second, although intuition might suggest that the constructive fields would be maximized directly between the prongs, the rapid decrease in field strength with distance from the conductor means the strongest signal is closest a prong.

Hall effect sensors and other vector magnetometers are capable of sensing this magnetic field, but packaged units cannot meet the proposed form factor needs or power requirements. Many such devices also fail to meet the requirements of this system's design due to low sensitivity or low sampling rates. Instead, it was observed that a surface mount wire wound inductor placed in the field can act as an inductive sensor or magnetometer. The alternating current in the wire causes a changing magnetic field which passes through the coils of the inductor and generates a voltage. A coil magnetometer used in this way is also known as a search coil.

$$V = - μ NA \frac{dH}{dt} \qquad ( 4 )$$

The equation governing the voltage generated in the coil can be determined from Faraday's law of induction and is shown in Equation (4), where μ is the magnetic permeability, N is the number of turns in the coil, and A is the cross-sectional area of the coil. Note that voltage is proportional to the change in magnetic field strength over time. This means that voltage on the inductor is proportional to the change in current over time, rather than the current itself. The signal must be integrated to recover the original current waveform.

If the form factor or power requirements prevent the use of a dedicated metering chip, then one option is to implement custom measurement software in a low power microcontroller. However, the choice of microcontroller must balance the fidelity of measurements with the availability of power. For example, a higher sampling rate will improve measurement accuracy, but it will also draw more power due to increased data conversion rate and more frequent processor wakeups. Similarly, the measurements themselves must be scaled from raw “ADC counts” to power statistics (W, VA, etc.) through various transfer functions that may require floating point arithmetic. The floating point operations could be performed on the energy meter itself, power and performance permitting, or they may be applied in the receiver. The particular operating point depends on a balance of many variables and will drive the implementation of the controller.

Data communication often requires a continuous burst of power. For a wireless radio, this is the energy required to send a single packet, but even a display screen must display for a minimum duration to allow a human to read it. In some cases, the current required may be more than what is available, and if so, the power supply must store at least the energy required for a single such event (referred to here as energy quanta). How much energy is available is determined by three components from FIG. 5: Z_{IN}, V_{Z}, and C_{OUT}.

Increasing C_{OUT} will increase the energy available, but at the expense of a slower recharge rate. Decreasing Z_{IN} results in greater current supply, which will increase both recharge rate and energy quanta (as additional current is available during the discharge event). Increasing V_{Z} will increase both energy quanta and recharge time, but will increase energy quanta more due to the quadratic term in energy calculation. Higher V_{Z} values are therefore preferred, but V_{Z} is also constrained by other components. Small options for C_{OUT} are commonly limited to 16 V, and many of the commercially available miniature buck converters offer significantly higher efficiencies in the 10-15 V range.

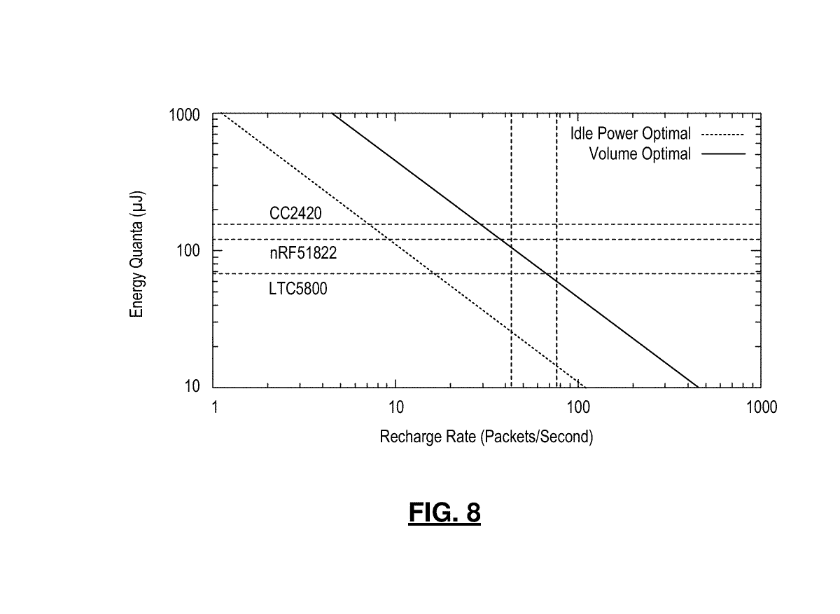

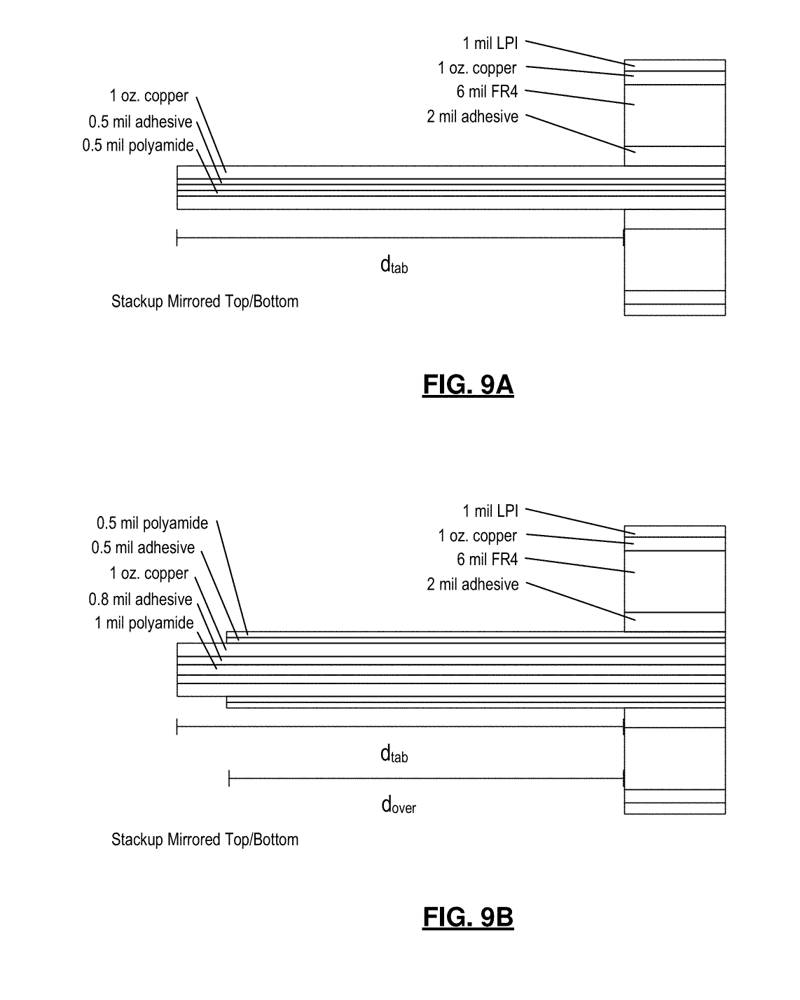

FIG. 8 shows the recharge rate and energy quanta for two of the three pareto-optimal options for the passive input impedance Z_{IN}. The current optimal option is not shown; it could supply sufficient current to continuously operate certain radios but is undesirable due to its high idle power draw. V_{Z} is fixed at 10 V, and for a given curve, increasing C_{OUT} results in moving up and to the left. The range of capacitance shown for each curve (up to 22 μF) is readily available in a variety of small ceramic packages.

Also shown is the minimum energy required to boot and send a packet for three possible radios, the CC2420 (Texas Instruments CC2420 RF transceiver), LTC5800 (Linear technology LTC5800 wireless mote-on-chip), and nRF51822 (Nordic Semiconductor Bluetooth Smart SoC). The energy quanta figures need not be exact; their purpose is to drive the selection of a radio.

For a given radio and selection Z_{IN}, the maximum recharge rate, in packets per second, is the intersection of the two lines. This can be used to determine the possible data rate or, if the required recharge rate is lower, Z_{IN} can be reduced from the optimal to reduce the idle power. The latter is the case in the example embodiment of the proposed energy meter.

Several components for the passive input impedance Z_{IN} are explored to evaluate their performance. Table 1 shows the expected maximum current from the supply and the experimentally measured actual current, as well as the volume, cost, and idle power that result from that component being selected. Resistors are able to deliver comparable current to that of capacitor shunts for a smaller volume and lower cost, but they increase idle power draw even when the load is powered off.

TABLE 1

| Z_{IN} (Z) | Expected | Actual | Volume | Cost | Idle Power |
|---|---|---|---|---|---|
| 22 nF (120 kΩ) | 456 μA | 451 μA | 43.0 mm³ | $1.24 | 0 mW |
| 33 nF (80 kΩ) | 705 μA | 740 μA | 43.0 mm³ | $1.63 | 0 mW |
| 56 nF (47 kΩ) | 1161 μA | 1137 μA | 95.0 mm³ | $1.34 | 0 mW |
| 100 kΩ | 550 μA | 538 μA | 2.6 mm³ | $0.03 | 140 mW |
| 80.6 kΩ | 687 μA | 658 μA | 3.0 mm³ | $0.03 | 170 mW |
| 75 kΩ | 733 μA | 716 μA | 3.0 mm³ | $0.03 | 190 mW |

Although earlier versions of the energy meter had footprints for both a 2220 package capacitor and 1210 package resistor, current designs optimize for size and cost by only providing space for the resistor. In addition to the significantly smaller size, the low cost of a resistor outweighs the cost added by its idle power. At $0.12 per kilowatt-hour, the 170 mW added by and 80 k′Ω resistor would outweigh the cost of a 33 nF capacitor only after nine years of continuous operation. In one example embodiment, a 80.6 k′Ω resistor is used, which leads to a design constraint for the rest of the system in that it must operate below a maximum average current of about 658 μA. Summing the power draw of the system and the idle power draw of the supply, this leads to an overall power draw of 176 mW for the energy meter. Present choices reflect the desire for frequent data transmissions supporting interactive use, but note that higher input impedance values Z_{IN} are also possible with a concomitant reduction in data transmission rate.

In the example embodiment, the remainder of the components from FIG. 5 are a 10 V Zener diode and 250 mA rectifier diode, both in a small SC-79 package, and a combined 55 μF from two parallel capacitors for C_{OUT}. A larger capacitance is selected than the minimum required from FIG. 8 to allow tolerance in the design, and the added delay is only experienced when the unit is first powering on. The load will nominally see 8.9 V: the Zener voltage minus the rectifier forward voltage of 1.1 V. To regulate this output to 3.3 V, a 3.3 V buck regulator is used, for example commercially available from Texas Instruments (i.e., TPS62122). At the nominal input voltage of 8.9 V, this regulator has an efficiency of 85-90%.

Voltage sensing in this form factor requires a planar contact method, a voltage divider, and an ADC to acquire the voltage signal digitally. Of these, the method to contact AC voltage is the only requirement that cannot be solved with small, readily available components. Consequently, the voltage sense circuit includes one or more input terminals that physically contact the prongs of the plug passing through a given cutout in the circuit board. Different options for contacting a prong of the plug as described below.

For example, the input terminal is a conductive member integrated into and coplanar with the circuit board. More specifically, the conductive member protrudes inwardly from a side wall defining the hole through which the prong passes. Because the manufacturing process of the circuit board itself produces the contact method, there are no additional parts or assembly required.

FIG. 9A depicts an example embodiment for an input terminal integrated into a circuit board. The circuit board is comprised of four copper layers with the inner two layers disposed on a flexible poly amide core and the outer two layers disposed on rigid glass-reinforced epoxy laminate (e.g., FR4). Through most of the area of the board, the stackup is rigidized by the FR4 and functions as a standard four layer circuit board. The inner layers are used for Power and Ground planes as in a typical system. However, the inner flexible polyamide and the two inner copper layers extend unsupported. This results in the flexible input terminal, conductive on either side. This can be electrically isolated from the Power and Ground planes inside the system, and routed to the power supply circuit 21 and voltage sensing circuits 23.

Although the input terminal 91 shown in FIG. 9A makes contact with the AC plug, the input terminal has very little elasticity and does not return to original shape when the plug is removed. This design can be improved by making two modifications to the construction. First is to increase the thickness by 3 mil overall and to strengthen it with additional overlays, which both increase elasticity and reduce the break risk. Second is to significantly reduce the length of the tab, decreasing the total deflection while the plug is connected and increasing the lifetime of the tab.

The augmented layer stackup for this alternative embodiment is shown in FIG. 9B. In this embodiment, the inner polyamide layer is doubled from 0.5 mil to 1 mil. In addition, on either side of the tab, add a 0.5 mil polyamide overlay with 0.5 mil adhesive that extends through most of the length of the terminal leaving the conductive tip exposed. This overlay, combined with the increased core thickness, results in a stronger and more elastic tab. By reducing the thickness of other layers, the overall PCB thickness is unchanged, which maintains the same available component volume.

In addition to modifying the PCB construction, the tab length is significantly reduced to reduce bend. The total cutout width for each prong is about 0.1″, and the prong itself occupies nominally 0.06″. The cutout is not centered on the plug, the free space is distributed about 0.01″ away from the tab and 0.03″ toward the tab but exact plug dimensions vary widely. A tab length of 0.03″, therefore, will only just make contact with the nominal plug width.

To determine the appropriate lengths of the tab and the overlay, four combinations were implemented and evaluated. The four options are shown in Table 2 below.

TABLE 2

| Option # | d_{tab} | d_{over,top} | d_{over,bot} |
|---|---|---|---|
| 1 | 0.035″ | 0.012″ | 0.012″ |
| 2 | 0.035″ | 0.030″ | 0.030″ |
| 3 | 0.045″ | 0.040: | 0.040″ |
| 4 | 0.045″ | 0.045″ | 0.012 |

Tab option 1 is 0.035″ long, with minimal bend as only 0.005″ of the tab overlaps the plug. This option has only 0.012″ of overlay on either side, just enough to strengthen the vertex. Tab option 2 is the same overall length, but with a longer overlay almost to the edge to determine the potential to improve elasticity. Tab option 3 is longer with more bend, but also a long overlay. Finally tab option 4 is a special case—a longer tab with the top side fully covered and therefore non-conductive. The plug must therefore be inserted from the back of the unit, but this option evaluates the maximum potential support provided by a single overlay.

Another option is to mount a spring loaded pin sideways in the plane of the PCB. If the tip of the pin is rounded, the AC plug can slide past it as the spring-loaded pin applies contact. Such components are available off the shelf (Mill-Max discrete spring loaded contacts), and since they are designed to be compressed, they will maintain contact over more insertions than flexible tabs. The tradeoff is in the difficulty in manufacturing. However, the spring loaded pins do afford the benefit of repeatability, they are designed to be used for a similar purpose and provide a significantly longer lifetime than tabs. Other approaches for implementing an input terminal that physically contact the plug also fall within the broader aspects of this disclosure.

Two calibration steps may be performed before the energy meter is put into use. The first step is to measure the scaling and offset values α and β, which must be done once per design. The second step is device-specific calibration that accounts for slight variations between units.

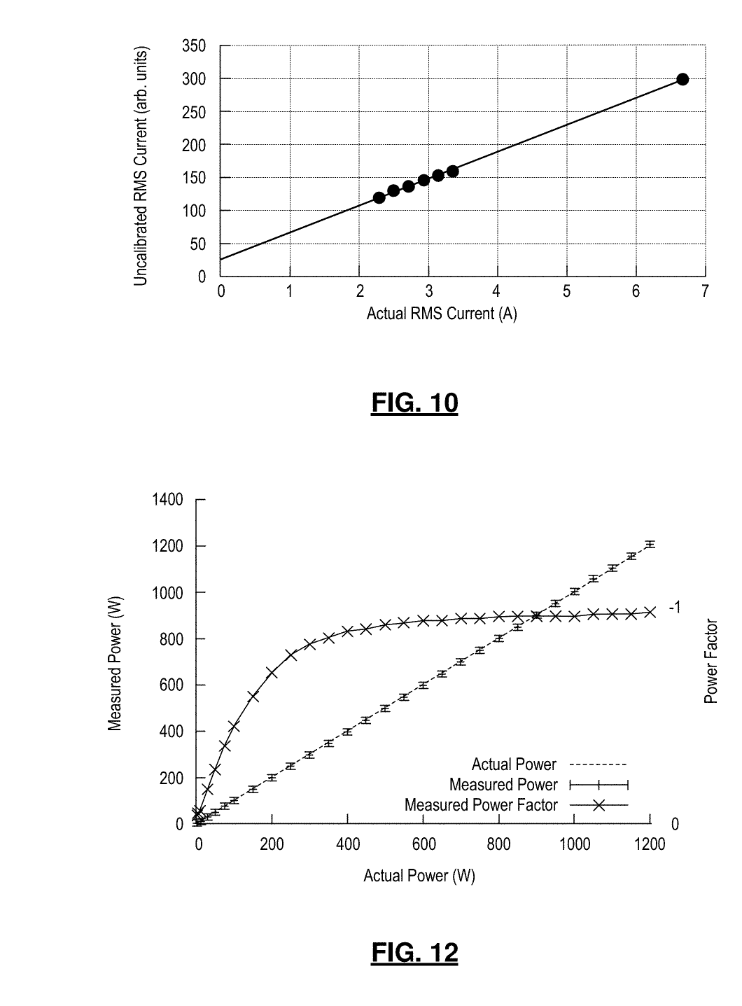

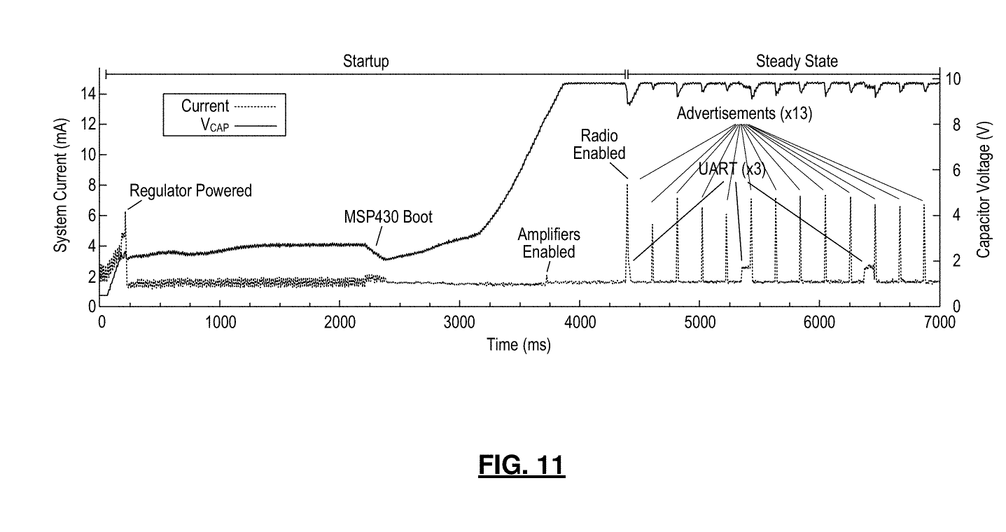

To determine the scaling and offset values α and β, respectively, one can measure the reported RMS current from the energy meter for a range of resistive (unity power factor) loads. FIG. 10 shows the RMS values of current reported as raw values. For the example embodiment, these measurements are linear with an R² value of 0.999, and indicate α of 40.85 and β of 25.0. The current calibration approach calls for α and β to be calculated for each energy meter within the unit itself.

To reduce the computational burden on the energy meter, divide by α in the receiver, and for increased accuracy, each unit is calibrated again. Connect each energy meter in a batch to a 200 W load to compute a device-specific α, store that value in ferroelectric random-access memory (FRAM), and transmit it with each packet. It was observed a mean value for α across multiple units of 41.79, with a 95% confidence interval of 1.87. Other techniques for calibrating the energy meter are envisioned by this disclosure.

In one embodiment, overhead of a power metering IC is saved by performing power metering calculations on a low power microcontroller, such as the MSP430FR5738 microcontroller available from Texas Instruments. This chip is the master controller of the system and is the only component not automatically power gated at startup. It is selected due to its small size, power efficiency of 81.4 μA/MHz, and integrated 16 kB non-volatile FRAM, eliminating an external component.

To measure power, the microcontroller samples V_{SENSE} and I_{SENSE} at 2.52 kHz (42 samples per AC cycle). This frequency is both an even divisor of the timing clock (32,768 Hz) and an even multiple of the frequency to be sampled (60 Hz). Because I_{SENSE} is proportional to the derivative of current, the second measurement step integrates I_{SENSE} to obtain current (V_{SENSE} is a good representation of voltage). The integration is performed in software, but could be performed by hardware in other embodiments. The final calculation step involves calculating power from voltage and current.

Because the microcontroller has real-time access to both voltage and current waveforms, it can function as a true power meter. Real power is determined by multiplying voltage and current at each point, and then averaging over the number of samples. Apparent power is determined by first calculating the root mean square voltage and current over a cycle, V_{RMS} and I_{RMS}, respectively, and then multiplying them. Knowledge of both real and apparent power allows the system to determine reactive power as well as the power factor of the load. Real power is also aggregated in the microcontroller to compute total watt-hours measured over time, and this number is stored in FRAM.

Data are transmitted in broadcast-style BLE advertisement messages. The MSP430 first communicates to the nRF51822 via UART at 38,400 baud, and the nRF51822 repeats this data in the advertisement. The MSP430 sends UART data nominally at 1 Hz, and the nRF51822 sends advertisements a 5 Hz, so 4-5 identical packets are transmitted each second. This greatly increases the likelihood of reception, and does not dramatically affect the power draw.

In addition to a sequence identifier and information regarding versioning and scaling, each energy meter packet contains four fields: line voltage, instantaneous real power, instantaneous apparent power, and watt-hours. Real power and apparent power are 1-second averages, and can be used together to calculate power factor. Watt-hours is an over-time total, and in the event of zero packet loss watt-hours will, once scaled, also equal the integral of real power.

The energy meter is robust against packet loss. The intended recipient of broadcast advertisements is either a smartphone or fixed BLE receiver, but in the event of no receiver, only the resolution of the missed packet is lost. The overall watt-hours total remains an accurate reading in any received packet. In one example, Watt-hours is stored as a 32-bit number and can overflow. In the worst case with present calibration scaling values, measuring an 1,800 W load will lead to an overflow every 29 days. A 100 W load will overflow after 523 days of continuous measurement. Overflows are signaled in the advertisements so the true watt-hours reading can be recovered. If a receiver is not present for long periods of time, potential for data loss exists.

FIG. 11 shows the startup phase of the energy meter 10 and 7 s of steady-state operation. When the system first starts, there is only power to boot the MSP430; if more components are drawing power, the 3.3 V power rail will never enable and the system will lock up. Instead, MOSFETs separately power gate the sensing circuits and BLE radio. With only the MSP430 running, the capacitor charges, enables the 3.3 V rail, and eventually reaches a nominal 8.9 V.

When the MSP430 detects that the capacitor has charged to the nominal voltage it enables the sensing circuits, and these remain powered for as long as the energy meter is powered. The MSP430 spends is collecting measurements before enabling the nRF51822, which also remains powered for the duration of the trace. At this point the device has entered steady-state operation.

The proposed energy meter 10 is evaluated on the basis of accuracy in reporting real power for both a calibrated resistive AC load and an assortment of household loads. First, bench top accuracy is explored. The energy meter 10 is used to measure the power draw of a programmable AC load—the APS 3B012-12 (ABS 3B series datasheet)—set to unity power factor. This allows one to measure a large part of the metering range (up to 1200 W) in defined increments and in a controlled setting. Second, the energy meter 10 is used to measure the power draw of several household items. Although not an exhaustive list, this is representative of the target usage.

For the bench top accuracy, ground truth is provided by the 3B012-12 itself via its serial interface. For the household tests, ground truth is taken from two sources. On the low range, a professionally calibrated Power Line Meter (PLM) is used. This device is limited to 480 W, however, so to measure larger loads take ground truth from a Watts Up Pro plug load meter. The Watts Up measurement is reported over the low range as well, and it is clear that it is less accurate than the PLM (typical error of about 1.72%). The need to use two different meters for ground truth demonstrates the difficulty in creating a highly accurate whole-range metering solution. For each test, take 30 measurements using the proposed energy meter, 30 ground measurements, and report the arithmetic mean and 95% confidence interval.

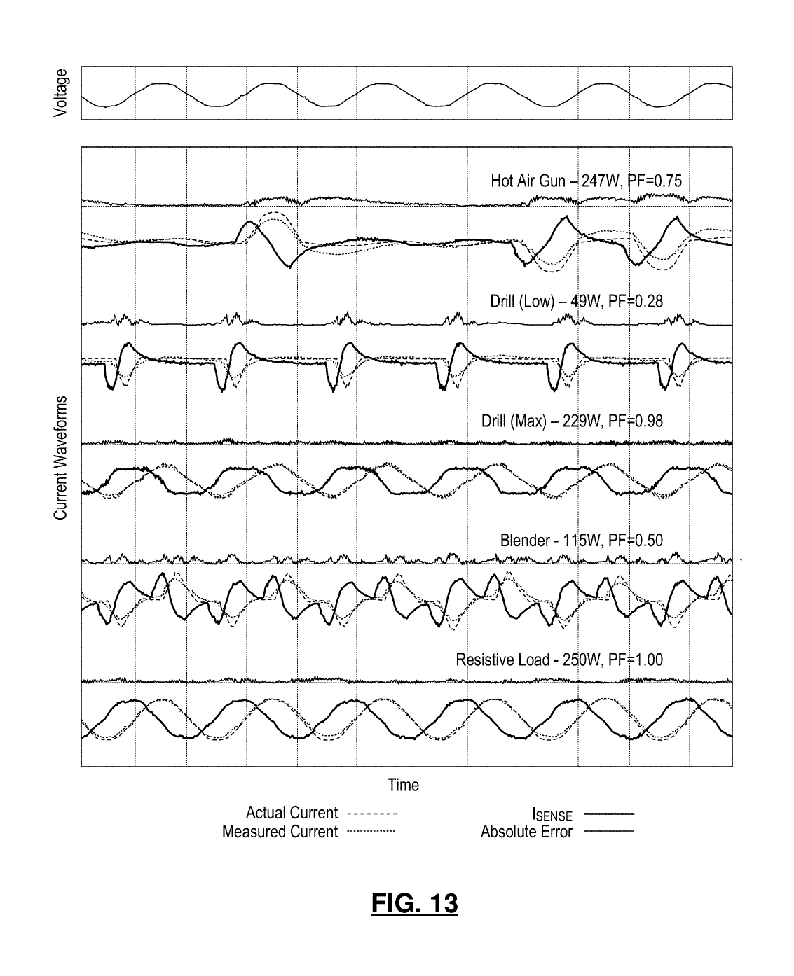

Resistive loads with a unity power factor, which include incandescent lights and power-factor-corrected devices, exhibit a sinusoidal current waveform in-phase with voltage. To measure the energy meter's 10 accuracy in this simple but common case, an APS 3B012-12 programmable AC load set to a fixed unity power factor is used. FIG. 12 shows the end-to-end accuracy for the energy meter metering this resistive load. Displayed are the reported real power and power factor from the energy meter 10, as well as the ground truth power up to the programmable load's maximum of 1200 W. Note that the true power factor is equal to one throughout the test.

Next, measure 29 wattages from 2.2 W to 1200 W: 50 W to 1200 W in increments of 50 as well as 2.2 W, 5 W, 10 W, and 75 W. For these measurements the average error is 2.3 W and the average percent error is 1.13%. At 2.2 W the error is 0.21 W (9.5%) and at 1200 W the error is 7.01 W (0.6%).

Resistive loads constitute a large fraction of household devices, but not all loads have sinusoidal current waveforms. Table 3 shows the proposed energy meter's 10 accuracy for several devices found in a common household. For these devices, simultaneously take a measurement using the proposed energy meter and a Watts Up meter, and if the load is below 480 W, a PLM measurement. If available, the PLM is used as ground truth. If not, the Watts Up measurement is used. Although the fridge draws about 100 W, its start-up power tripped the 4 A fuse in the PLM, preventing PLM measurements for that load. For each device, power and power factor, as well as error are reported for the energy meter 10 and, if not used as ground truth, the Watts Up device for comparison.

TABLE 3

| Device | PF | Power | | Watts Up Error | | PowerBlade Error | |
|---|---|---|---|---|---|---|---|
| 150 W Bulb | 1.00 | 162.17 | W | 1.22 W | (0.75%) | −0.99 W | (0.61%) |
| Fridge | 1.00 | 108.22 | W | — | | −5.30 W | (4.90%) |
| Drill (Max) | 0.99 | 235.21 | W | 1.69 W | (0.72%) | 2.96 W | (1.26%) |
| Toaster | 0.99 | 827.87 | W | — | | −22.11 W | (2.67%) |
| Vacuum | 0.98 | 1246.96 | W | — | | 15.24 W | (1.22%) |
| Microwave | 0.92 | 1729.73 | W | — | | 16.01 W | (0.93%) |
| Hot Air | 0.83 | 305.54 | W | 0.88 W | (0.29%) | −1.93 W | (0.63%) |
| TV (Normal) | 0.62 | 196.23 | W | 0.86 W | (0.44%) | −9.03 W | (4.60%) |
| 50 W CFL | 0.61 | 48.57 | W | −1.08 W | (2.22%) | −9.51 W | (19.58%) |
| TV (Static Image) | 0.61 | 129.51 | W | −0.04 W | (0.03%) | −4.00 W | (3.09%) |
| Xbox | 0.57 | 50.44 | W | 0.64 W | (1.27%) | −0.83 W | (1.65%) |
| MacBook | 0.51 | 52.68 | W | −0.41 W | (0.78%) | −4.49 W | (8.52%) |
| Blender | 0.49 | 106.63 | W | 1.95 W | (1.83%) | 36.97 W | (34.67%) |
| Router | 0.46 | 9.11 | W | 0.22 W | (2.41%) | −0.62 W | (6.81%) |
| Drill (Low) | 0.30 | 51.10 | W | 4.18 W | (8.18%) | 20.40 W | (39.92%) |

This set of devices has a range of power from 9 W to 1730 W and a range of power factors from 0.30 to 1. The average absolute error for measurements of these devices is 10 W (4.3× higher than the resistive load), and the average percent error is 6.5% (5.8× higher). This error is dominated by two devices with highly inductive (low power factor) draws: the blender (PF=0.49) and the drill set to low power (PF=0.30). Each of these devices has an error of over 20 W and a percent error of over 30%, and excluding these two, the average absolute error drops to 7.2 W (3.1× the resistive load) and the average percent error drops to 4.3% (3.8× the resistive load).

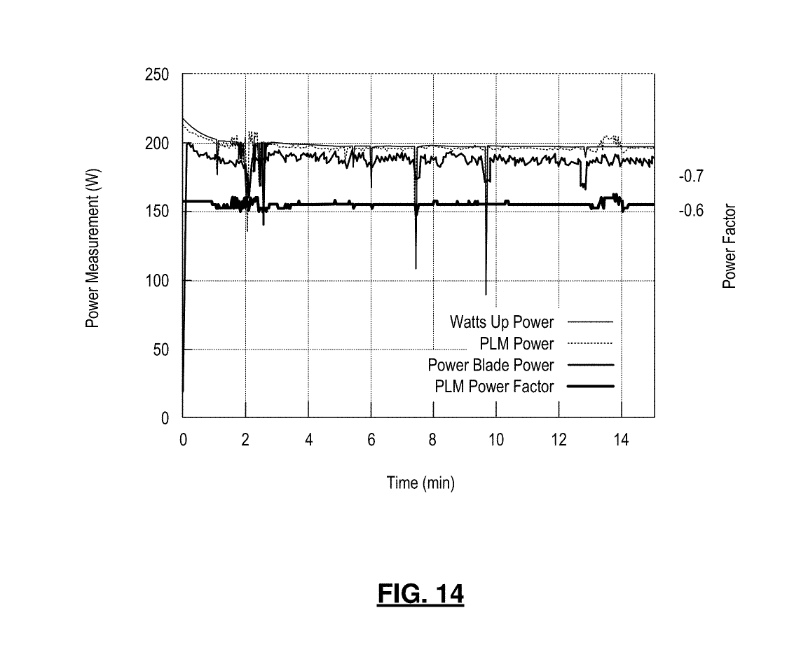

The difficulty in measuring highly inductive loads, and further the difference in accuracy between the programmable load and the household devices, can be partially explained by examining the current waveforms. FIG. 13 visualizes the current measurement process in the proposed energy meter 10 for a few loads from Table 3. The known current signal, measured by a commercial current transformer (LEMM TT 100-SD current transformer), is shown along with I_{SENSE}, the signal output from PowerBlade's current amplifier (which, as described above, represents the derivative of the current waveform). Also shown in this post-integration representation of current. Voltage for each load is synchronized, and zero crossings of the common voltage are denoted by vertical lines.

Visible on the figure is the integral/derivative relationship between I_{SENSE} and known current, as well as the fidelity of the integrated signal to that known current. For devices with sinusoidal or otherwise smooth current waveforms, the integrated signal tracks well with known current. For other devices, however, high frequency components in the current waveform are suppressed by the integrator, resulting in increased error.

The energy meter 10 is designed to measure and report both instantaneous power and watt-hours, the sum over time that will be used by the utility company to levy charges. The figure of watt-hours also accounts for the possibility that one or multiple packets are not received: resolution is lost but watt-hours remains an accurate long-term measure. To evaluate accuracy in reporting watt-hours, simultaneous measurements are taken from the PLM, Watts Up, and the energy meter 10 for a television in normal viewing use. FIG. 14 shows the measurements over time from Watts Up and the energy meter as compared to the PLM.

After 15 minutes of normal television use, the PLM reported 49.07 Wh, the Watts Up reported 49.28 Wh (0.42% error), and the energy meter 10 reported 46.80 Wh (4.62% error). In instantaneous measurement trials the measurements for the television in full use were off by an average of 4.60%, the watt-hours figure of 4.62% error is consistent with the instantaneous readings.

The energy meter 10 accuracy makes it comparable to other power metering systems, but it is the usability of the system, and in particular the size, cost, and wireless communications, that most distinguish it.

The defining characteristic of the energy meter 10 is its volume: the entire system is a single PCB. This circuit board is 1.0″ on a side, and the PCB itself is 0.023″ thick. The thickest component on the surface is the antenna at 0.043″, so the combined total thickness of the system is 0.066″. This is the same thickness as the pass-through section of the FlipIt charger, which is a certified commercial product.

The component breakdown for the example embodiment, of the energy meter 10 with costs is listed below in Table 4.

TABLE 4

| Component | Cost | Component | Cost |
|---|---|---|---|
| MSP430FR5738 | $1.71 | Sense inductor | $0.30 |
| nRF51822 | $1.66 | Amplifiers | $2.51 |
| Antenna, balun, & crystals | $1.70 | MOSFETs | $0.12 |
| Buck converter | $0.65 | Other passives | $0.93 |
| | | PCB | $1.47 |

| | |
|---|---|
| Total | $11.05 |

Prior to consumer use, the energy meter needs and enclosure, but the system could be largely assembled for $10-$15 per unit. Although it is important to note the distinction between the cost of the energy meter 10 and the price of other systems, this is slightly less than the price Kill-A-Watt ($23.99) and significantly less than the price of Watts Up ($130.95). The cost of $10-$15 for the energy meter 10 is also an un-optimized reporting of DigiKey pricing; the minimum viable cost would likely be much lower.

The effectiveness of communications was tested by measuring packet reception rates in three configurations of the energy meter 10. First, a single meter was deployed and evaluated as a baseline. Next, three meters were placed throughout a room as a more typical deployment case. Finally, the three meters were placed on a single power strip and activated simultaneously to test for possible packet collisions. Both unique and total packets received per second were recorded. The energy meter updates data at 1 Hz, and BLE packets are sent at 5 Hz, so nominally one should receive 1 unique and 5 total packets per second.

For each configuration packet reception rate was evaluated at three transmission distances, and performed both in an apartment and in a lab. The apartment consists of three rooms, with measurements taken in the same room, adjacent room, and two rooms away. Only a single other BLE device is active in the apartment. The lab consists of one room and hallways, and measurements are taken in the same room, immediately outside of the room in the hallway, and 20 m down the hallway from the room. The lab environment includes 16 other BLE devices as well as numerous other devices active in the 2.4 GHz band.

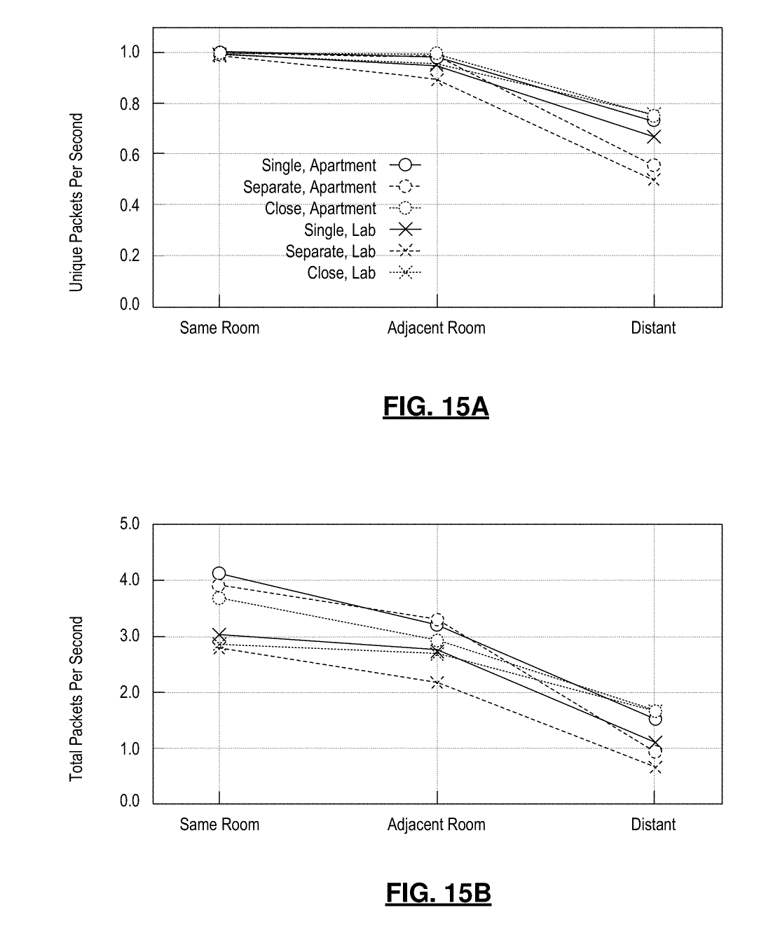

FIG. 15 shows the reception rate for each of these trials, In all cases, the unique reception rate is at or close to the nominal of 1 per second when in the same or adjacent rooms, but the total reception rate decreases from the same to the adjacent room. Further, the total reception rates are higher in the apartment than in the lab for both distances. Taken together these three results suggest that range and interference do effect BLE transmission, but the redundancy in the energy meter 10 helps ensure reliable data communication.

The distant measurements show continued decline in total packets, but also a decrease in unique packets: 20% to 50% of the unique packets are not received at all (all five redundant packets were all dropped). This indicates that this distance—whether two rooms separated in a residential setting or 20 m down a hall away in a university building—exceeds the energy meter's usable range. Note that RF designs require some degree of lumped-parameter tuning to achieve maximum performance but RF circuitry has not been tune yet, so that may help explain these results.

The state-of-the-art in plug-load metering fails to provide consumers and corporations the detailed knowledge they need to understand and adjust their energy consumption patterns at a size, cost, power, and usability point that permits widespread adoption. While plug loads represent one of the faster growing segments of electrical loads, existing systems for measuring them remain too expensive, draw too much idle power, lack a wireless interface, and are often too large or too cumbersome to easily deploy.

To address the gap between emerging needs and existing solutions, a new power/energy meter design was presented above that enables a new paradigm in metering by making the sensor so small and unobtrusive that it can be permanently attached to a plug rather than an outlet. The proposed energy meter accurately meters the power of a load in real-time and wirelessly transmits that data to nearby smartphones or gateways using a Bluetooth Low Energy radio. With a thickness of mere sixteenth of an inch, the energy meter is the first power meter that is truly plug-through. Realizing this diminutive form factor, however, requires revisiting all of the key design choices for a power meter.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. An energy meter for use with a device having a power cord, comprising:
a circuit board having a set of holes configured for prongs of an electric plug to pass therethrough;
a current sense circuit mounted onto the circuit board, the current sense circuit includes an inductor that is disposed proximate to a given hole in the set of holes and configured to measure magnetic field generated by current flowing through a prong passing through the given hole;
a voltage sense circuit mounted onto the circuit board and configured to measure voltage between two specific prongs passing through the set of holes, where the voltage sense circuit includes input terminals that physically contact the two specific prongs and electrically couples the two specific prongs to the voltage sense circuit; and
a microcontroller mounted onto the circuit board and is electrically coupled to the current sense circuit and the voltage sense circuit, wherein the microcontroller computes electrical power of load supplied by the electric plug from the measured magnetic field and the measured voltage.

2. The energy meter of claim 1 wherein the inductor is orientated such that windings of the inductor wind around an axis that is parallel to a plane defined by the circuit board.

3. The energy meter of claim 1 wherein the inductor of the current sense circuit is further defined as a horizontally wirewound inductor.

4. The energy meter of claim 1 wherein at least one of the input terminals of the voltage sense circuit is a conductive member integrated into and coplanar with the circuit board, where the conductive member protrudes inwardly from a side wall defining the hole through which the specified prong passes through.

5. The energy meter of claim 1 further comprises a power supply circuit mounted to the circuit board, where the power supply circuit is configured to receive AC voltage from the prongs of the electrical plug and operates to rectify and down convert the AC voltage to a lower DC voltage.

6. The energy meter of claim 5 wherein power supply circuit electrically couples via the input terminals to the two specific prongs.

7. The energy meter of claim 5 wherein the power supply circuit is further defined as a Zener regulated power supply with a passive input impedance element and a half-wave rectifier.

8. The energy meter of claim 7 wherein the passive input impedance circuit element is a ceramic capacitor.

9. The energy meter of claim 1 wherein the microcontroller includes a ferroelectric random-access memory that stores the computed electrical power.

10. The energy meter of claim 1 further comprises a wireless interface mounted to the circuit board and interfaced with the microcontroller to report the computed electrical power.

11. The energy meter of claim 10 wherein the wireless interface is further defined as a wireless transmitter.

12. The energy meter of claim 1 wherein the circuit board has length and width that is one inch or less.

13. An energy meter for use with a device having a power cord, comprising:
a circuit board having a set of cutouts configured for prongs of an electric plug to pass therethrough;
a power supply circuit mounted to the circuit board, where the power supply circuit is configured to receive AC voltage from a specified prong passing through one of the cutouts in the set of cutouts and operates to rectify and down convert the AC voltage to a lower DC voltage;
a current sense circuit mounted onto the circuit board, the current sense circuit includes an inductor that is disposed proximate to a given cutout in the set of cutouts and configured to measure magnetic field generated by current flowing through a prong passing through the given cutout;
a voltage sense circuit mounted onto the circuit board and configured to measure voltage between two specific prongs passing through the set of cutouts, where the voltage sense circuit includes input terminals that physically contacts the two specific prongs and electrically couples the two specific prongs to the voltage sense circuit;
a microcontroller mounted onto the circuit board and is electrically coupled to the current sense circuit and the voltage sense circuit, wherein the microcontroller computes electrical power of load supplied by the electric plug from the measured magnetic field and the measured voltage; and
a wireless transmitter mounted to the circuit board and interfaced with the microcontroller to transmit the computed electrical power.

14. The energy meter of 13 wherein the inductor is orientated such that windings of the inductor wind around an axis that is parallel to a plane defined by the circuit board.

15. The energy meter of claim 13 wherein the inductor of the current sense circuit is further defined as a horizontally wirewound inductor.

16. The energy meter of claim 13 wherein at least one of the input terminals of the voltage sense circuit is a conductive member integrated into and coplanar with the circuit board, where the conductive member protrudes inwardly from a side wall defining the hole through which the specified prong passes through.

17. The energy meter of claim 13 wherein the power supply circuit is further defined as a Zener regulated power supply with a passive input impedance element and a half-wave rectifier.

18. The energy meter of claim 17 wherein the passive input impedance circuit element is a ceramic capacitor.

19. The energy meter of claim 13 wherein the microcontroller includes a ferroelectric random-access memory that stores the computed electrical power.

20. The energy meter of claim 13 wherein the circuit board has a that is one inch or less and a width that is one inch or less.
